(19) United States
(12) Patent Application Publication
(10) Pub. No.: US 2002/0187619 A1
(43) Pub. Date: Dec. 12, 2002

(54) Gettering process for bonded SOI wafers

(75) Inventors: Richard L. Kleinhenz, Wappingers Falls, NY (US); Daniel Moy, Bethel, CT (US); Robert E. Bendernagel, Carmel, NY (US); Harold J. Hovel, Katonah, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY

(21) Appl. No.: 09/849,296

(22) Filed: May 4, 2001

(51) Int. Cl. H01L 21/322

(52) U.S. Cl. 438/471

(57) ABSTRACT

A method for gettering metallic impurities located in a semiconductor substrate. In an exemplary embodiment of the invention, the method includes forming an insulating layer upon a donor wafer. A cleaving layer is ionically implanted, through the insulating layer, into the donor wafer. The cleaving layer is formed at a first depth with respect to the insulating layer. A gettering layer is also ionically implanted, through the insulating layer, into the donor wafer. The gettering layer is formed at a second depth with respect to said insulating layer, with second depth being less than the first depth. The donor wafer is then bonded, at the insulating layer, to a substrate wafer. The donor wafer is then fractured along the cleaving layer, and a section of the donor wafer is removed along the cleaving layer. Thereby, an active semiconductor device area is formed atop the gettering layer.

### BACKGROUND OF THE INVENTION

The present invention relates generally to semiconductor processing and, more particularly, to techniques for gettering metallic impurities introduced in integrated circuits during the manufacturing of bonded SOI wafers.

Metallic impurities have harmful effects upon the circuit components of an integrated circuit fabricated on an active semiconductor layer. During the fabrication of silicon on insulator (SOI) devices, metallic impurities may be introduced into the devices as a result of high current oxygen ion implantation and annealing related diffusion. These impurities, if left in the near surface area where the devices are formed, have an adverse effect on the performance and yield of the devices.

Intrinsic gettering involves the creation of gettering sinks (also referred to as “damage sites”), such as crystal defects or oxygen precipitates, in the semiconductor substrate at a distance from the front side of the substrate. The substrate is then heated to facilitate the diffusion of the impurities in the substrate where they are then trapped or absorbed by the gettering sinks. For example, U.S. Pat. No. 5,244,819, issued to Yue, discloses a method for gettering contamination from a thin film SOI or SOS (silicon on sapphire) device. Damage sites are created by ion implantation into the inactive region only of the device in order to cause diffusion of metallic contamination from the active region to the inactive region. In U.S. Pat. No. 6,001,711, issued to Hashimoto, there is disclosed a process of forming a heavily doped damaged layer which is subsequently annealed by heat treatment so as to form a heavily doped buried layer and a gettering site layer.

Backside or extrinsic gettering involves creating damage sites on the backside of the wafer. The damage sites may be introduced by such techniques as diffusion, deposition, ion implantation or mechanical means. Again, the goal is for the metallic impurities to diffuse to the damage sites and become trapped therein. In the processing of SOI wafers, however, the active area is located within an epitaxial layer having an oxygen concentration which is too low for effective internal gettering. In addition, the direct implantation of an ionic gettering layer through the active layer can render the wafer unsuitable for processing. Furthermore, backside gettering does not work for an SOI device because the active layer is located atop a buried silicon dioxide insulating layer. The damage sites, if created on the back side of the wafer, would therefore be located on the opposite side of (under) the silicon dioxide layer. As such, the metallic impurities would not able to diffuse through the buried insulating layer to the damage sites.

A need, therefore, exists for an improved process for gettering metallic contaminants within semiconductor devices, particularly contaminants in SOI wafers.

### BRIEF SUMMARY OF THE INVENTION

The above discussed and other drawbacks and deficiencies of the prior art are overcome or alleviated by a method for gettering metallic impurities located in a semiconductor substrate. In an exemplary embodiment of the invention, the method includes forming an insulating layer upon a donor wafer. A cleaving layer is ionically implanted, through the insulating layer, into the donor wafer. The cleaving layer is formed at a first depth with respect to the insulating layer. A gettering layer is also ionically implanted, through the insulating layer, into the donor wafer. The gettering layer is formed at a second depth with respect to said insulating layer, with second depth being less than the first depth. The donor wafer is then bonded, at the insulating layer, to a substrate wafer. The donor wafer is then fractured along the cleaving layer, and a section of the donor wafer is removed along the cleaving layer. Thereby, an active semiconductor device area is formed atop the gettering layer. In a preferred embodiment, the cleaving layer comprises ionically implanted hydrogen atoms and the gettering layer comprises an inert material such as argon or nitrogen atoms.

### BRIEF DESCRIPTION OF THE DRAWINGS

Referring to the exemplary drawings wherein like elements are numbered alike in the several Figures:

FIGS. 1-5 are simplified diagrams illustrating a method for gettering metallic impurities in a semiconductor substrate, in accordance with an embodiment of the invention; and

FIGS. 6-9 are simplified diagrams illustrating an alternative embodiment of the method illustrated in FIGS. 1-5.

### DETAILED DESCRIPTION OF THE PREFERRED EMBODIMENT

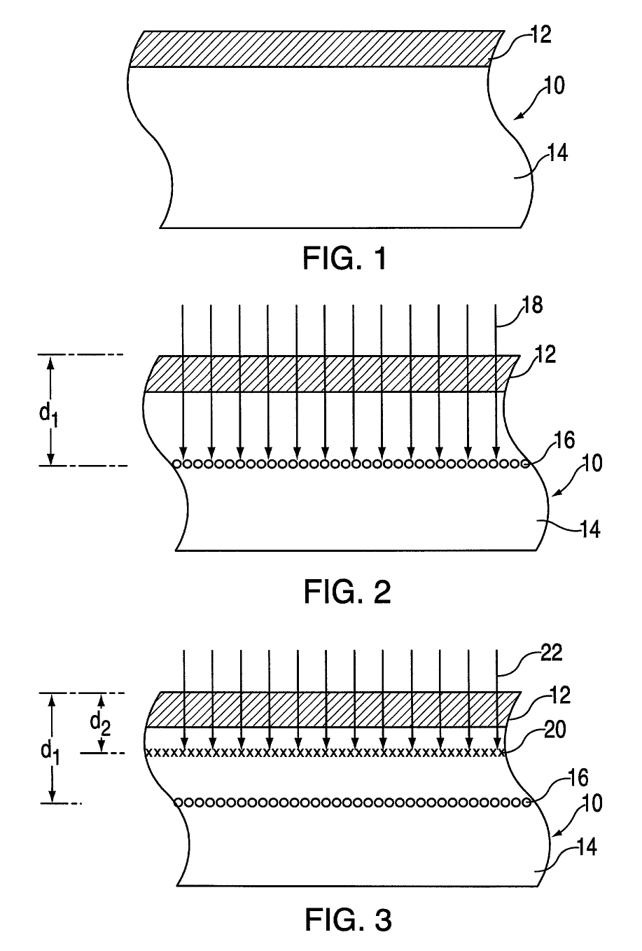

Referring initially to FIGS. 1 through 5, a method for gettering metallic impurities in a semiconductor substrate in accordance with an embodiment of the invention is shown. Beginning in FIG. 1, a donor wafer 10 has an insulating oxide layer 12 formed thereupon. Preferably, the donor wafer substrate 14 is comprised of monocrystalline silicon.

In FIG. 2, a cleaving layer 16 is formed within the substrate 14 of the donor wafer 10 by a first ion implantation, as indicated by arrows 18. The first implantion involves forming a layer of gaseous microblisters within the volume of the wafer 10 at a first depth, d₁, approximately equal to the average ion penetration depth. In particular, the cleaving layer 16 preferably comprises ions of hydrogen gas. During the implantation of the cleaving layer 16, the donor wafer 10 should be kept at a temperature below the temperature at which the atoms of implanted gas can escape by diffusion from wafer 10. In the present embodiments, the term “gaseous microblister” refers to any cavity of micro-cavity generated by the implantation of ions in the substrate material. The cavities may be in a flattened form, having a very low height. In other words, the cavity height may be a few inter-atomic distances and the cavity shape may be substantially spherical. Further, the cavities may contain a free gaseous phase and/or atoms of gas derived from implanted ions fixed on the atoms of the material forming the cavity walls. The cavities may also be referred to as “platelets”, “microblisters” or “bubbles”.

The first depth d₁ and the ion implantation energy are interrelated. For a given type of implanted ion, the implantation depth and energy are mainly determined by the nature of the semiconductor material used. For example, in the case of a hydrogen ion implantation into a silicon substrate, the relationship between the implantation depth and the implantation energy are shown below in Table I:

TABLE I

| | | | | |
|---|---|---|---|---|
| Thickness | 5 μm | 10 μm | 30 μm | 100 μm |
| Energy | 500 keV | 750 eV | 1500 keV | 3200 keV |

In order for the substrate film to be rigid enough for cleaving, it is recommended that first depth d₁ be at least 5 μm in thickness. As shown in Table 1, the minimum requred implantation energy for a 5 μm cleaving layer 16 depth is about 500 keV. Furthermore, the minimum required implantation dose of hydrogen ions is about 5×10¹⁶/cm². Naturally, the selection of first depth d₁ of cleaving layer 16 is dependent upon the ultimate desired thickness of the final semiconductor device. Additional description on the first implantation process may be found in U.S. Pat. No. 5,714,395, issued to Bruel, which is incorporated herein by reference.

FIG. 3 illustrates a second ion implantation process whereby a gettering layer 20 is also formed (indicated by arrows 22) within the donor wafer substrate 14. As is seen in FIG. 3, the second implantation is executed an energy such that gettering layer 20 is formed at a second depth, d₂, that is just below the insulating oxide layer 12. The gettering layer 20 is preferably comprised of ions of an inert gas, such as argon or nitrogen. However, those skilled in the art will easily appreciate that other elements may be used in forming a gettering layer.

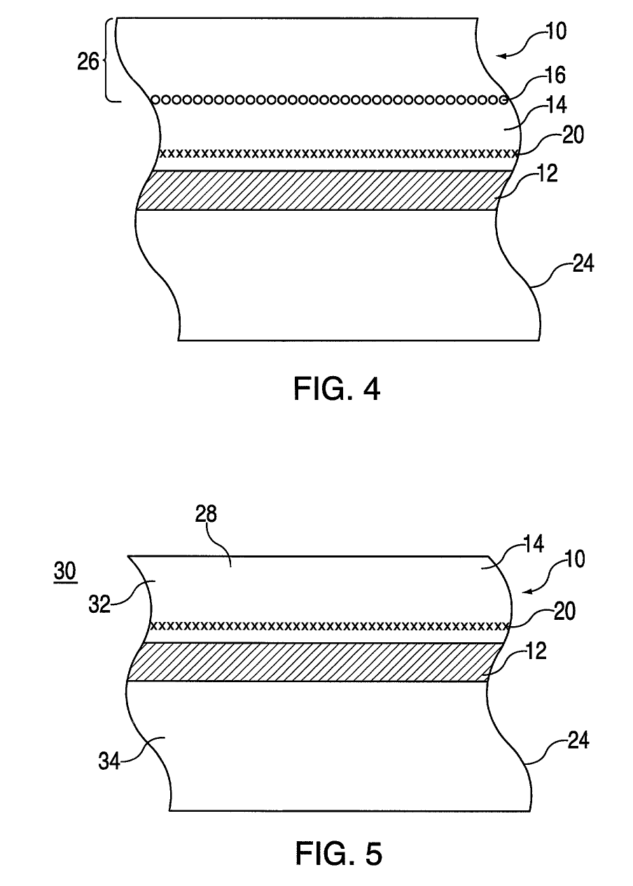

Following the second ion implantation, the donor wafer 10 is “flipped” and bonded to a substrate wafer 24 at the insulating oxide layer 12 of donor wafer 10, as shown in FIG. 4. Thus bonded, the insulating oxide layer 12 becomes a buried oxide layer. Then, the donor wafer 10 is fractured, and a section 26 thereof is separated and removed at the cleaving layer 16 upon heat treatment. The separation at the cleaving layer 16 is caused by a pressure effect in the gaseous microblisters. However, the heat treatment should be performed at a temperature low enough so as not to anneal and repair the damaged area formed by gettering layer 20 introduced during the second ion implantation process.

Finally, the top surface 28 of the remaining section of donor wafer 10 may be planarized by techniques such as chemical mechanical polishing (CMP), or the like. A SOI structure 30 is thereby formed having an active layer 32, a buried insulating layer 12 and a substrate 34, as shown in FIG. 5. The gettering layer 20 is located near the bottom of the active layer 32 and has therefore been introduced without unnecessarily damaging the main body of the active layer 32.

Referring once again to FIG. 4, an alternative step of fracturing and separating the section 26 of donor wafer 10 may be employed. Rather than applying heat to a microblister formation, a controlled cleaving process may be implemented. The cleaving layer 16, however, is still introduced into the donor wafer 10, as described above. In order to cleave a section of the donor wafer 10, energy may be applied to a selected region of the donor wafer 10, thereby forming a cleave front. The cleave front is then propagated within the substrate 14 by further application of subsequent, selective energy impulses until separation is achieved. Examples of the applied energy source to the substrate include, but are not limited to, a chemical source, a mechanical source, an electrical source and a thermal source, and/or any combination therebetween. A more detailed explanation of this controlled cleaving process may be found in U.S. Pat. No. 6,010,579, issued to Henley et al, the contents of which are incorporated herein by reference.

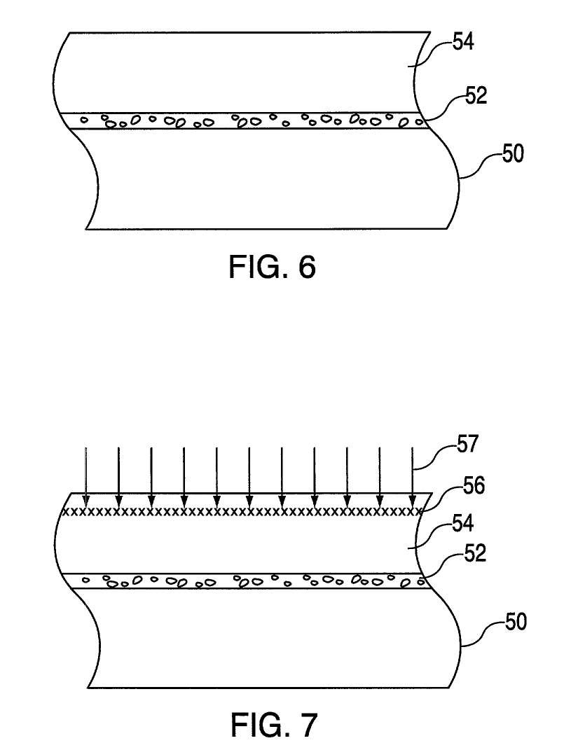

Referring generally now to FIGS. 6 through 9, an alternative embodiment of the above described gettering process is shown. Beginning in FIG. 6, a donor silicon wafer 50 has a porous silicon layer 52 formed thereupon. The mechanical strength of porous silicon is much lower than that of bulk silicon, depending on the porosity thereof. For example, porous silicon having a porosity of 50% is considered to have half the mechanical strength of bulk silicon. Upon the application of a tensile, compressive or shearing force to a laminated wafer, the porous layer will be broken first.

A silicon substrate may be made porous by anodization in a hydroflouric acid (HF) solution. The resulting porous silicon layer will have a density ranging from 1.1 to 0.6 g/cm³, depending on the concentration of the HF solution from 20% to 50%. Monocrystalline silicon has a density of 2.33 g/cm³. It should be noted that a porous layer may be formed only upon a p-type silicon substrate, as is described in U.S. Pat. No. 5,856,229 to Sakaguchi, which is incorporated herein by reference.

Next, an epitaxial layer 54 of silicon is grown atop the porous layer 52. Because the internal pores of porous layer may be rearranged at temperatures of 1000° C. or higher, however, low temperature growth processes are preferred for the epitaxial growth of the silicon layer 54. Such processes include, but are not limited to, molecular beam epitaxial growth, plasma chemical vapor deposition (CVD), reduced pressure CVD, photo-assisted CVD, bias sputtering and liquid-phase epitaxial growth.

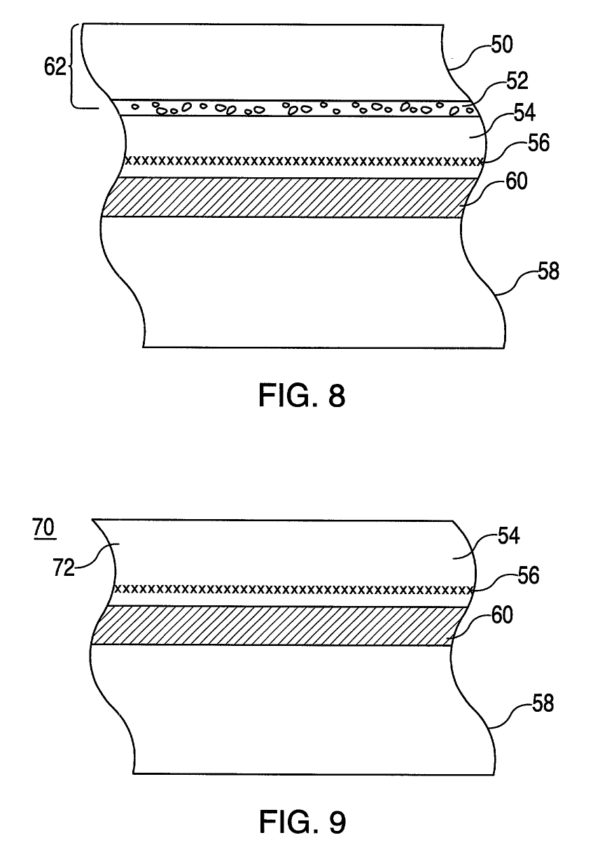

Once the epitaxial layer 54 is grown, a gettering layer 56 is ionically implanted therein as shown in FIG. 7. The ionization, indicated by arrows 57, is preferably carried out in the same manner as shown in FIG. 3 of the first embodiment. The implantation of the gettering layer 56 is performed at an energy so as to form the gettering layer 56 just below the surface of the epitaxial layer 54. Following implantation, the donor wafer 50 is “flipped” and bonded to a substrate wafer 58, the substrate wafer 58 already having an insulating oxide layer 60 formed thereupon, as shown in FIG. 8.

Finally, FIG. 9 illustrates the process following the removal of a section of the donor wafer 50 at the porous layer 52. The porous layer 52 may be selectively removed by non-electrolytic wet chemical etching, using a typical silicon etching solution such as hydroflouric acid or a mixture of hydroflouric acid with alcohol and/or hydrogen peroxide. A section 62 of the donor wafer 50 (shown in FIG. 8) is thus separated from the substrate wafer 58, thereby resulting in a SOI structure 70 now having a buried oxide layer 60 and a gettering layer 56 (atop the oxide layer) in an active layer 72 of monocrystalline silicon.

Through the foregoing description, it is seen that a gettering layer for trapping metallic impurities may be formed over a buried oxide layer without the direct implantation of the gettering layer into the active layer of the wafer. By implanting the gettering layer into a donor wafer, flipping and bonding the donor wafer to a substrate wafer, and finally removing a section of the donor wafer according to one of the techniques described above, the deficiencies and drawbacks of the prior art may be overcome. While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for gettering metallic impurities located in a semiconductor substrate, comprising:
forming an insulating layer upon a donor wafer;
ionically implanting, through said insulating layer, a cleaving layer in said donor wafer, said cleaving layer formed at a first depth with respect to said insulating layer;
ionically implanting, through said insulating layer, a gettering layer in said donor wafer, said gettering layer formed at a second depth with respect to said insulating layer, said second depth being less than said first depth;
bonding said donor wafer, at said insulating layer, to a substrate wafer;
fracturing said donor wafer along said cleaving layer; and
removing a section of said donor wafer, along said cleaving layer, thereby forming an active semiconductor device area atop said gettering layer.

2. The method of claim 1, wherein said cleaving layer comprises ionically implanted hydrogen atoms.

3. The method of claim 1, wherein said gettering layer comprises an inert material.

4. The method of claim 3, wherein said gettering layer comprises ionically implanted nitrogen atoms.

5. The method of claim 3, wherein said gettering layer comprises ionically implanted argon atoms.

6. The method of claim 1, wherein said insulating layer is formed by oxidizing said donor wafer.

7. The method of claim 1, wherein said cleaving layer further comprises microblisters formed within said donor wafer.

8. The method of claim 7, wherein said cleaving layer is fractured by heat treatment.

9. The method of claim 1, wherein said cleaving layer is fractured by propagating a cleave front through said donor wafer.

10. A method for gettering metallic impurities located in a semiconductor substrate, comprising:
forming a porous layer upon a donor wafer;
growing an epitaxial layer upon said porous layer;
ionically implanting a gettering layer in said epitaxial layer;
bonding said donor wafer, at said epitaxial layer, to an insulating layer, said insulating layer formed atop a substrate wafer;
removing said porous layer and separating a top section of said donor wafer from said substrate wafer;
wherein an active semiconductor device area is defined within said epitaxial layer and atop said gettering layer.

11. The method of claim 10, wherein said porous layer is formed by anodizing said donor wafer in a hydroflouric acid solution.

12. The method of claim 10, wherein said porous layer is removed by non-electrolytic wet chemical etching.

13. The method of claim 10, wherein said gettering layer comprises an inert material.

14. The method of claim 13, wherein said gettering layer comprises ionically implanted nitrogen atoms.

15. The method of claim 13, wherein said gettering layer comprises ionically implanted argon atoms.

16. The method of claim 10, wherein said epitaxial layer comprises monocrystalline silicon.
